(19) United States
(12) Patent Application Publication
(10) Pub. No.: US 2014/0151870 A1
(43) Pub. Date: Jun. 5, 2014

(54) SEMICONDUCTOR PACKAGE INCLUDING A HEAT-SPREADING PART AND METHOD FOR ITS MANUFACTURE

(71) Applicant: DONG-KWAN KIM, Hwaseong-si (KR)

(72) Inventor: DONG-KWAN KIM, Hwaseong-si (KR)

(21) Appl. No.: 14/071,601

(22) Filed: Nov. 4, 2013

(30) Foreign Application Priority Data
Nov. 30, 2012 (KR) 10-2012-0138255

(51) Int. Cl. H01L 23/34

(52) U.S. Cl. CPC H01L 23/34
USPC 257/712

(57) ABSTRACT

A semiconductor package includes a substrate, a semiconductor chip attached to an upper surface of the substrate, a molding material configured to surround side surfaces of the semiconductor chip, and a heat-spreading part disposed on the semiconductor chip. The heat-spreading part includes a thermal conductive film and a heat slug that are integrated together. Also provided is a method for its manufacture.

### CROSS-REFERENCE TO RELATED APPLICATION

This application claims priority under 35 U.S.C. §119 to Korean Patent Application No. 10-2012-0138255 filed on Nov. 30, 2012, the disclosure of which is hereby incorporated by reference in its entirety.

### BACKGROUND

1. Technical Field

Embodiments of the inventive concept relate to a semiconductor package including a heat-spreading part in which a thermal conductive film and a heat slug each of uniform thickness across their planar extent are integrated together.

2. Description of Related Art

Recently, mobile products have come to require a semiconductor package characterized by their uniform thin-ness. Thus, various thermal spreading parts capable not only of enabling a uniformly thin semiconductor package to be manufactured but also of maximizing heat radiation efficiency have been suggested.

### SUMMARY

Embodiments of the inventive concept provide a semiconductor package having a uniformly thin thickness.

Embodiments of the inventive concept also provide a semiconductor package including a heat-spreading part having high thermal conductivity.

Embodiments of the inventive concept also provide a semiconductor package including a thermal spreading part in which a thermal conductive film and a heat slug are integrated together.

Embodiments of the inventive concept also provide a method of manufacturing such a semiconductor package by disposing an integral and relatively thin heat-spreading part characterized by uniform thickness (the heat-spreading part integrally vertically stacking and adhering a planar thermal conductive heat plug on a thin planar thermal conductive film) on an upper planar surface of a substrate-mounted semiconductor chip and an upper co-planar surface of a molding material surrounding at least lateral sides of the semiconductor chip, thereby producing a semiconductor package characterized by less thickness, more thermal radiation efficiency, and greater durability (e.g. against a known peeling-off phenomenon), all by way of reduced processing time (e.g. against additionally applying a heat emission material) and thus at lower cost.

The technical objectives of the inventive concept are not limited to the above disclosure; other objectives may become apparent to those of ordinary skill in the art based on the following descriptions.

In accordance with an aspect of the inventive concept, a semiconductor package includes a substrate, a semiconductor chip attached to an upper surface of the substrate, a molding material configured to surround side surfaces of the semiconductor chip, and a heat-spreading part disposed on the semiconductor chip. The heat-spreading part includes a heat slug and a thermal conductive film, the horizontal areas of which are substantially the same if not identical.

A surface of the thermal conductive film that is not attached to the heat slug may be attached to upper surfaces of the semiconductor chip and the molding material. The thermal conductive film and the heat slug may have the same size.

Corresponding side surfaces of the heat-spreading part, of the molding material and of the substrate may be vertically aligned with one another.

Corresponding side surfaces of the heat-spreading part and of a portion of the molding material adjacent to the heat-spreading part may be aligned with each other in a first vertical direction (i.e. a first vertical plane). Corresponding side surfaces of a remaining portion of the molding material and of the substrate adjacent to the remaining portion of the molding material may be aligned with each other in a second vertical direction (i.e. a second vertical plane). The side surfaces aligned in the first vertical direction and the side surfaces aligned in the second vertical direction may or may not be vertically aligned with each other.

### BRIEF DESCRIPTION OF THE DRAWINGS

The foregoing and other features and advantages of the inventive concepts will be apparent from the more particular description of exemplary embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1A is a schematic side cross-sectional view of a semiconductor package in accordance with a first embodiment of the inventive concept;

FIG. 1B is a schematic side cross-sectional view of a semiconductor package in accordance with a second embodiment of the inventive concept;

FIG. 2A is a schematic side cross-sectional view of a semiconductor package in accordance with a third embodiment of the inventive concept;

FIG. 2B is a schematic side cross-sectional view of a semiconductor package in accordance with a fourth embodiment of the inventive concept;

FIG. 3 is a flowchart conceptually illustrating a method of manufacturing a semiconductor package in accordance with an embodiment of the inventive concept;

FIGS. 4A to 4F are conceptual cross-sectional views illustrating a method of manufacturing a semiconductor package in accordance with a first embodiment of the inventive concept;

FIG. 5 is a conceptual side cross-sectional view illustrating a method of manufacturing a semiconductor package in accordance with a second embodiment of the inventive concept;

FIG. 6 is a conceptual side cross-sectional view illustrating a method of manufacturing a semiconductor package in accordance with a third embodiment of the inventive concept;

FIG. 7 is a conceptual side cross-sectional view illustrating a method of manufacturing a semiconductor package in accordance with a fourth embodiment of the inventive concept;

FIGS. 8A and 8B are conceptual side cross-sectional views illustrating methods of forming a semiconductor package in accordance with other embodiments of the inventive concept;

FIG. 9 is a diagram conceptually illustrating a semiconductor module including a semiconductor package in accordance with an embodiment of the inventive concept;

FIG. 10 is a block diagram conceptually illustrating an electronic system including a semiconductor package in accordance with an embodiment of the inventive concept;

FIG. 11 is a block diagram conceptually illustrating an electronic system including a semiconductor package in accordance with another embodiment of the inventive concept; and

FIG. 12 schematically illustrates a mobile wireless phone including a semiconductor package in accordance with an embodiment of the inventive concept.

### DETAILED DESCRIPTION OF THE EMBODIMENTS

Various embodiments of the inventive concept will now be described more fully with reference to the accompanying drawings in which some embodiments are shown. The inventive concept may, however, be embodied in different forms and should not be construed as limited to the embodiments set forth herein. Rather, these embodiments are provided so that this disclosure is thorough and complete and fully conveys the inventive concept to those skilled in the art. In the drawings, the sizes and relative sizes of layers and regions may be exaggerated for clarity. Thus, regions illustrated in the drawings are assigned broad attributes and do not limit the scope of the inventive concept. Like numerals refer to like elements throughout. Thus, even if the same or like reference numerals are not described with reference to a related drawing, they may be described with reference to another drawing. Also, even if an element is not assigned a reference numeral in a drawing, this element may be described with reference to other drawings.

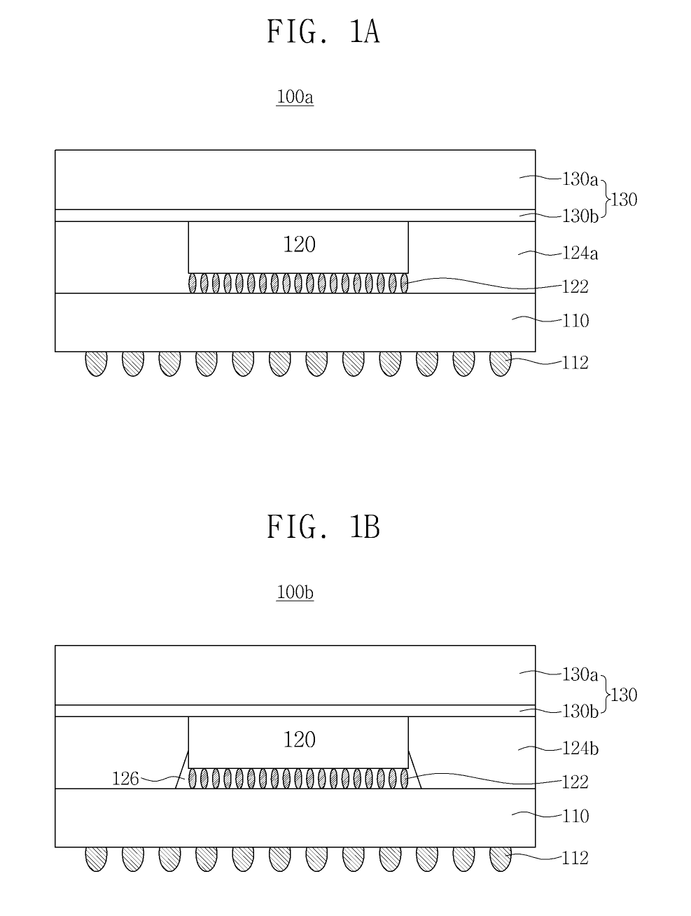

FIG. 1A is a schematic side cross-sectional view of a semiconductor package 100a in accordance with a first embodiment of the inventive concept. FIG. 1B is a schematic side cross-sectional view of a semiconductor package 100b in accordance with a second embodiment of the inventive concept.

Referring to FIG. 1A, the semiconductor package 100a in accordance with the first embodiment may include a substrate 110, a semiconductor chip 120 attached to an upper surface of the substrate 110, a molding material 124a surrounding the semiconductor chip 120, and a heat-spreading part 130 disposed on the substantially planar and the substantially entire upper surfaces of the molding material 124a and the semiconductor chip 120. The semiconductor package 100a may further include chip bumps 122 that electrically connect the semiconductor chip 120 and the substrate 110, and solder balls 112 attached to a lower surface of the substrate 110.

The substrate 110 may form a part or all of, or may include, a rigid printed circuit board (PCB), a flexible PCB, or rigid-flexible PCB.

The semiconductor chip 120 may include a logic semiconductor device. A logic semiconductor device may be any electronic device, other than a memory device, containing logic circuitry. The logic device may be, for example, a photoelectron device, a communication device, a digital signal processor (DSP), a general-purpose processor including a microprocessor, microcontroller, a combination of a DSP and microprocessor, an application-specific integrated circuit (ASIC), or a system-on-chip. The chip bumps 122 may include a mesa type metal filler or a solder material. The semiconductor chip 120 may be attached onto the substrate 110 via the chip bumps 122 using flip-chip technology.

The molding material 124a may surround side surfaces of the semiconductor chip 120 and the chip bumps 122. The molding material 124a may include an epoxy molding compound (EMC).

The heat-spreading part 130 may include a heat slug 130a and a thermal conductive film 130b.

The heat slug 130a may have a flat shape and may include a metal material, such as copper (Cu), aluminum (Al), or an alloy.

The thermal conductive film 130b may contact an upper surface of the semiconductor chip 120 and an upper surface of the molding material 124a. The thermal conductive film 130b may include epoxy resin that has high adhesive properties to be firmly attached to the molding material 124a. Also, the thermal conductive film 130b may include a filler having high thermal conductivity, e.g., aluminum oxide (Al₂O₃), silver, silicon dioxide (SiO₂), aluminum nitride (AlN), or boron nitride (BN). Also, the thermal conductive film 130b may include about 70% of aluminum oxide (Al₂O₃) having thermal conductivity of 1 watt per meter-° Kelvin (w/m-° K) in order to maintain hardness thereof. The thermal conductive film 130b may have adhesive properties itself or may be provided while being adhered with an additional thermal conductive adhesive tape. The adhesive tape may be a dual-face adhesive tape. Also, the thermal conductive film 130b may be formed to a thickness of between approximately five and one hundred micrometers (˜5-˜100 μm).

Referring to FIG. 1B, the semiconductor package 100b in accordance with the second embodiment may include a substrate 110, a semiconductor chip 120 disposed on the substrate 110, a molding material 124b surrounding side surfaces and lower surface of the semiconductor chip 120, a heat-spreading part 130 that covers a substantially entire upper surface of the semiconductor chip 120 and a substantially entire upper surface of the molding material 124b and includes a heat slug 130a and a thermal conductive film 130b that are vertically integrated together (i.e. disposed with substantially coextensive mating surfaces suitably bonded together into an integral, vertical stack structure), and an under-fill material 126 that is filled between the semiconductor chip 120 and the substrate 110 and surrounding the chip bumps 122. The semiconductor package 100b may further include chip bumps 122 formed between one surface of the semiconductor chip 120 and one surface of the substrate 110 to electrically connect the semiconductor chip 120 and the substrate 110, and solder balls 112 attached to another surface of the substrate 110.

The under-fill material 126 surrounding the chip bumps 122 may include a resin that has adhesive properties. The molding material 124b may be formed to surround side surfaces of the under-fill material 126 and the semiconductor chip 120.

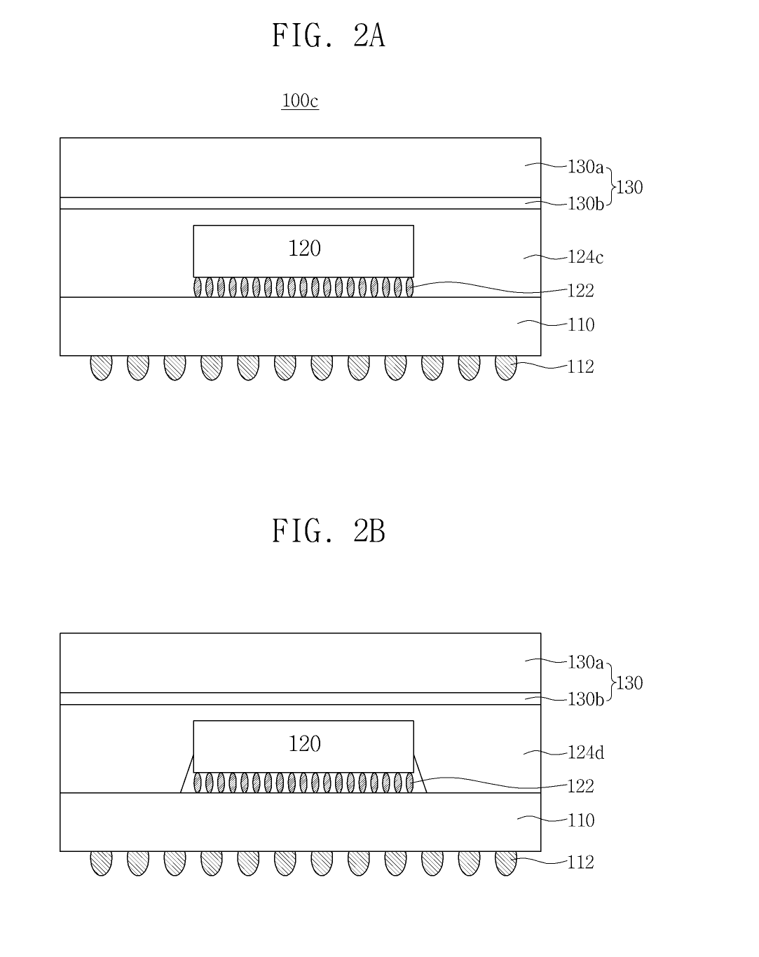

FIG. 2A is a schematic side cross-sectional view of a semiconductor package 100c in accordance with a third embodiment of the inventive concept. FIG. 2B is a schematic side cross-sectional view of a semiconductor package 100d in accordance with a fourth embodiment of the inventive concept. The difference between the embodiment of FIGS. 1A and 1B and that of FIGS. 2A and 2B is the extension of the molding material from the sides also to cover the top of the semiconductor chip in the latter embodiment.

Referring to FIG. 2A, the semiconductor package 100c according to the third embodiment may include a substrate 110, a semiconductor chip 120 disposed on the substrate 110, a molding material 124c surrounding side surfaces and a lower surface of the semiconductor chip 120 and covering a substantially entire upper surface of the semiconductor chip 120, and a heat-spreading part 130 that covers a substantially entire upper surface of the molding material 124c and includes a heat slug 130a and a thermal conductive film 130b that are vertically integrated together.

Referring to FIG. 2B, the semiconductor package 100d according to the fourth embodiment may include a substrate 110, a semiconductor chip 120 disposed on the substrate 110, an under-fill material 126 that is filled between the semiconductor chip 120 and the substrate 110, a molding material 124d surrounding side surfaces of the under-fill material 126 and the semiconductor chip 120 and covering a substantially entire upper surface of the semiconductor chip 120, and a heat-spreading part 130 that covers a substantially entire upper surface of the molding material 124d and includes a heat slug 130a and a thermal conductive film 130b that are vertically integrated together.

It may be seen, then, that according to the embodiments described and illustrated herein, a thinner and more thermally efficient electronic package may be manufactured. By spreading heat more evenly across the substantial entirety of the upper surface area of the semiconductor package, more thermally efficient, e.g. cooler, operation of the semiconductor package is realized. This advantage may be realized despite the continuous downward pressure on the overall thickness of electronic devices such as mobile phones, computer tablets, and digital cameras. Further, this advantage is realized in an integrated structure including, for example, the heat slug and the thermal conductive film that extend a uniformly thick, laminated, planar surface above the upper surfaces of the semiconductor package and of the molding material that at least substantially surrounds the semiconductor chip within the package.

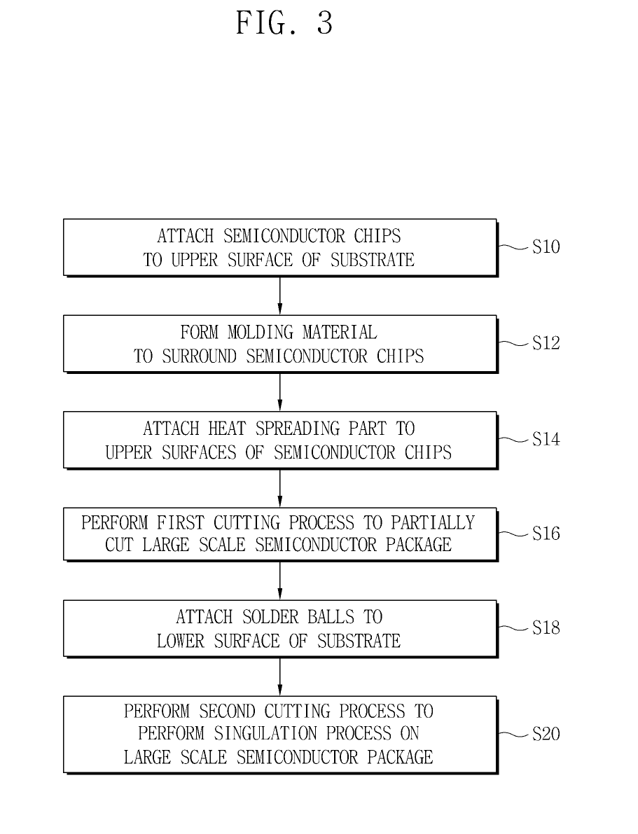

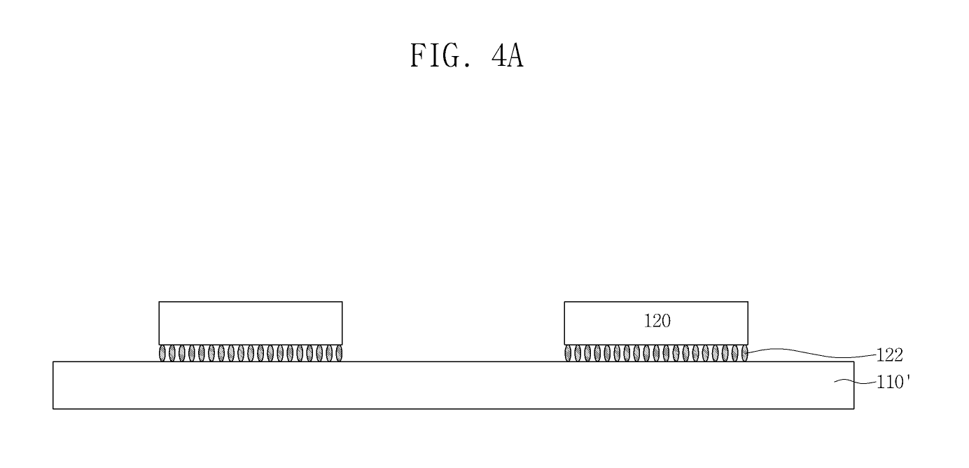

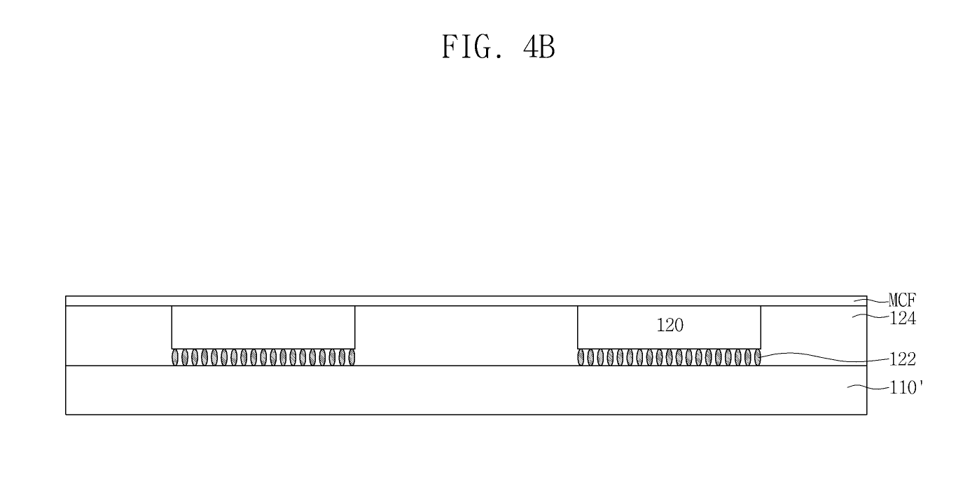

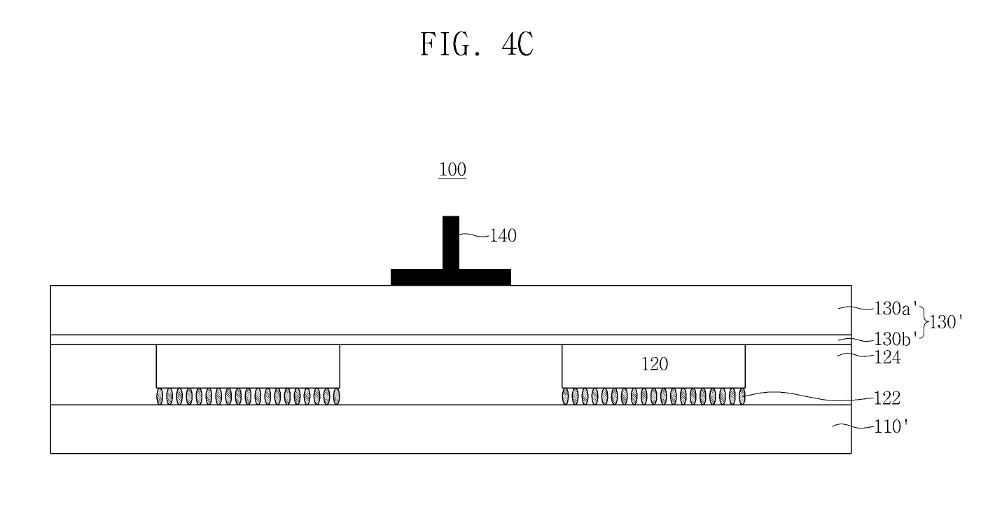

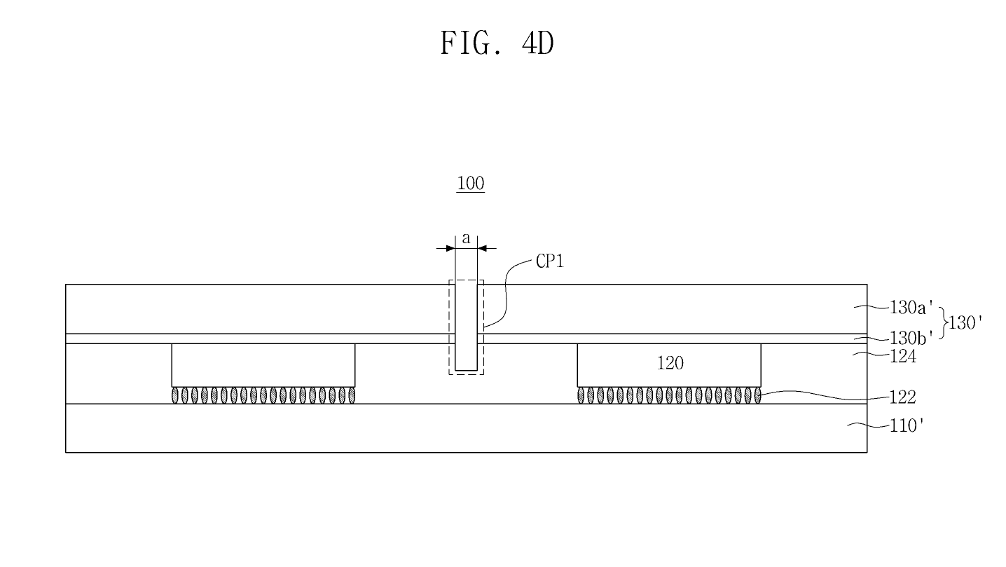

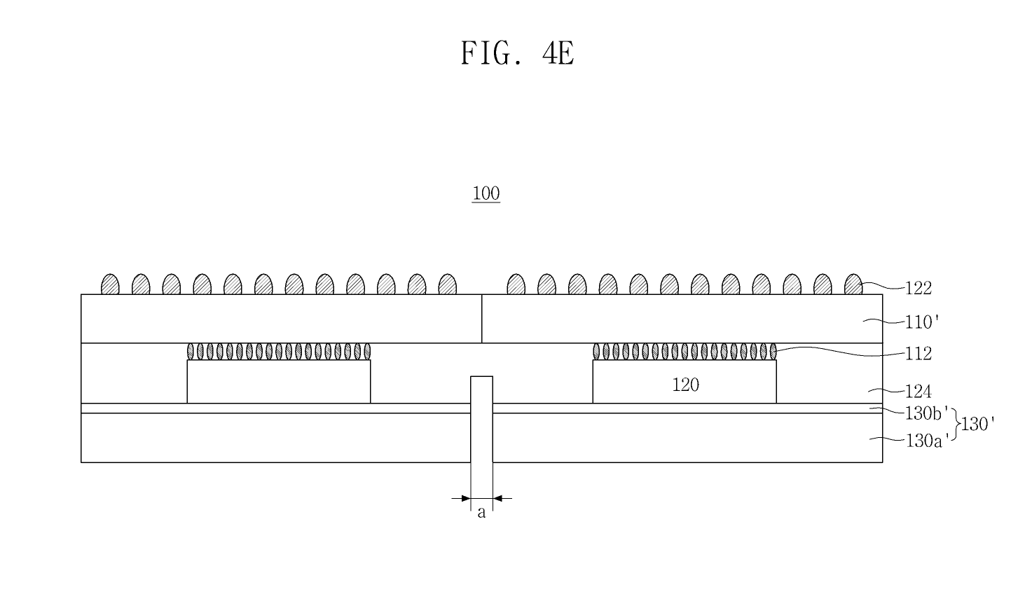

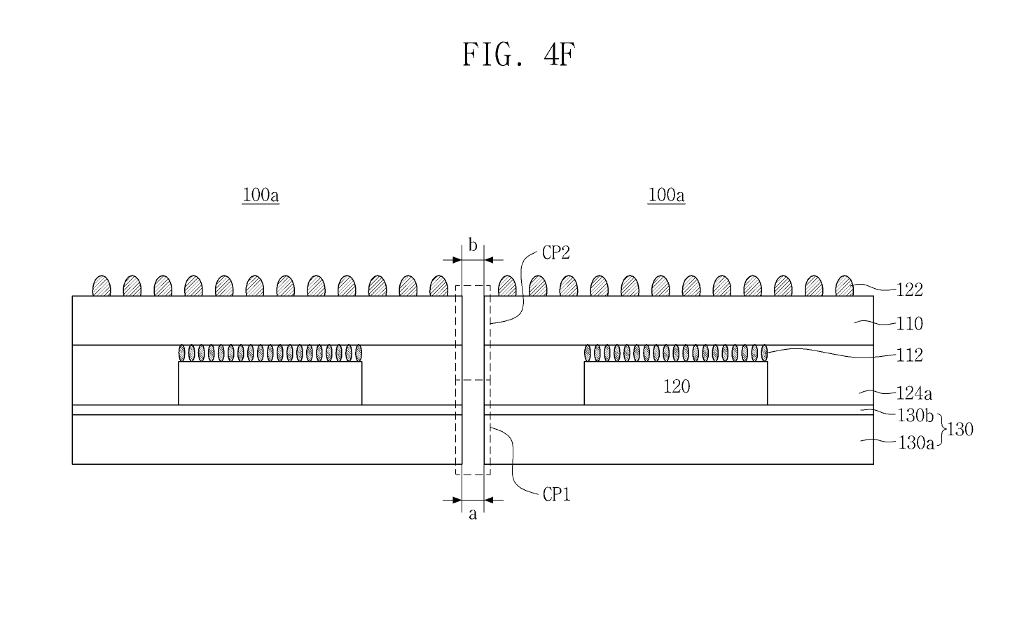

FIG. 3 is a flowchart conceptually illustrating a method of manufacturing a semiconductor package in accordance with an embodiment of the inventive concept. FIGS. 4A to 4F are conceptual cross-sectional views illustrating a method of manufacturing a semiconductor package in accordance with a first embodiment of the inventive concept.

Referring to FIGS. 3 and 4A, the method of manufacturing a semiconductor package in accordance with an embodiment of the inventive concept may include attaching semiconductor chips 120 to an upper surface of a large-scale substrate 110′ (operation S10). Chip bumps 122 are previously attached to one surface of the semiconductor chips 120. The chip bumps 122 attached to the semiconductor chips 120 may be physically and electrically attached and connected to the upper surface of the substrate 110 according to a re-flow process.

Then, referring to FIGS. 3 and 4B, the method of manufacturing a semiconductor package in accordance with an embodiment of the inventive concept may include forming a molding material 124 to surround the semiconductor chip 120 (operation S12). Methods of forming the molding material 124 may include a method of closely sticking, for example, a molding control film (MCF) to upper surfaces of the semiconductor chips 120 and filling a space between the MCF and the substrate 110′ with the molding material 124. In particular, the molding material 124 may be formed to surround side surfaces of the semiconductor chip 120 and the chip bumps 122 attached to a lower surface of the semiconductor chip 120.

Then, referring to FIGS. 3 and 4C, the method of manufacturing a semiconductor package in accordance with an embodiment of the inventive concept may include attaching a heat-spreading part 130′ to the upper surfaces of the semiconductor chips 120 (operation S14). The heat-spreading part 130′ may be attached to be closely stuck to the upper surfaces of the semiconductor chips 120 and the upper surface of the molding material 124. The heat-spreading part 130′ may include a heat slug 130a′ and a thermal conductive film 130b′ that are vertically integrated together. Methods of disposing the heat-spreading part 130′ to be closely stuck to the upper surfaces of the semiconductor chips 120 may include a thermo-compression bonding method. The thermo-compression bonding method is performed to apply heat and downward pressure onto an upper surface of the heat slug 130a′ of the heat-spreading part 130′ using a compressor 140. Through the thermo-compression bonding method using the compressor 140, the thermal conductive film 130b′ may be stably attached to the upper surfaces of the semiconductor chips 120 and the molding material 124. Thus, the large-scale semiconductor package 100 including the substrate 110′, the semiconductor chips 120 attached to one surface of the substrate 110′, the molding material 124 surrounding the semiconductor chips 120, and the heat-spreading part 130′ attached to the upper surface of the molding material 124 may be formed.

Then, referring to FIGS. 3 and 4D, the method of manufacturing a semiconductor package in accordance with an embodiment of the inventive concept may include performing a first cutting process to divide the large-scale semiconductor package 100 into a plurality of individual semiconductor packages (operation S16). The first cutting process may include a half cutting process of cutting a part CP1 of the thickness of the large-scale semiconductor package 100 (and perpendicularly to its plane). Thus, the first cutting process may include cutting the molding material 124 to a predetermined thickness, starting from an upper surface of a part of the heat-spreading part 130′ corresponding to the center of a space between the semiconductor chips 120. Through the first cutting process, the part CP1 of the heat-spreading part 130′ and the molding material 124 may be partially cut to have a first width a.

Then, referring to FIGS. 3 and 4E, the method of manufacturing a semiconductor package in accordance with an embodiment of the inventive concept may include attaching a plurality of solder balls 122 to a lower surface of the substrate 110′ (operation S18). Specifically, the large-scale semiconductor package 100 is turned upside down such that the lower surface of the substrate 110′ faces upward, and the plurality of solder balls 122 may be attached to a part of or to substantially the entire exposed lower surface of the substrate 110′ according to a soldering process.

Then, referring to FIGS. 3 and 4F, the method of manufacturing a semiconductor package in accordance with an embodiment of the inventive concept may include performing a second cutting process to perform a singulation process on the large-scale semiconductor package 100 (S20). The second cutting process is performed to cut the substrate and an uncut part CP2 of the molding material 124, and may include a process of cutting the substrate 110′ and the molding material 124 in a direction that extends coaxially with or perpendicularly from the part CP1 that is cut according to the first cutting process (and thus also perpendicularly to the plane of the semiconductor package). Through the second cutting process, the large-scale semiconductor package 100 may be divided into a plurality of individual semiconductor packages 100a, each including one semiconductor chip 120. In this case, a second width b of the part CP2 obtained by cutting the substrate 110′ and the molding material 124 through the second cutting process may be equal to the first width a of the part CP1 that is cut by use of the first cutting process.

Accordingly, the corresponding side surfaces of all of the heat-spreading part 130, the molding material 124a, and the substrate 110 may be vertically aligned in a co-planar relationship with one another.

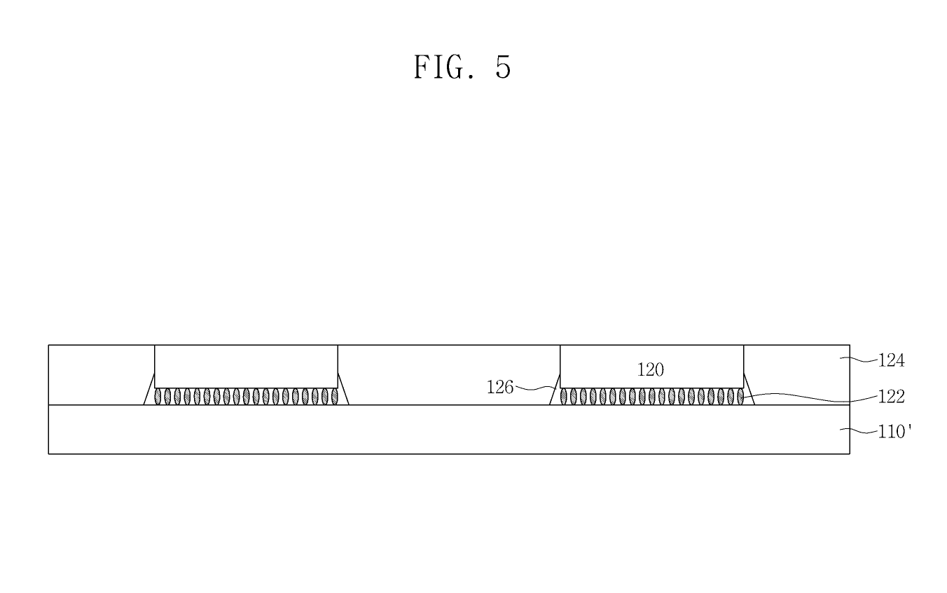

FIG. 5 is a conceptual side cross-sectional view illustrating a method of manufacturing a semiconductor package in accordance with a second embodiment of the inventive concept. In the method of manufacturing a semiconductor package according to the second embodiment, processes other than processes described below are the same as those of the first embodiment and are thus not repeated here. Referring to FIG. 5, the method of manufacturing a semiconductor package according to the second embodiment may include forming an under-fill material 126 to surround chip bumps 121 before a molding material 124 is formed. Thus, the molding material 124 may be formed to surround side surfaces of semiconductor chip 120 and side surfaces of the under-fill material 126.

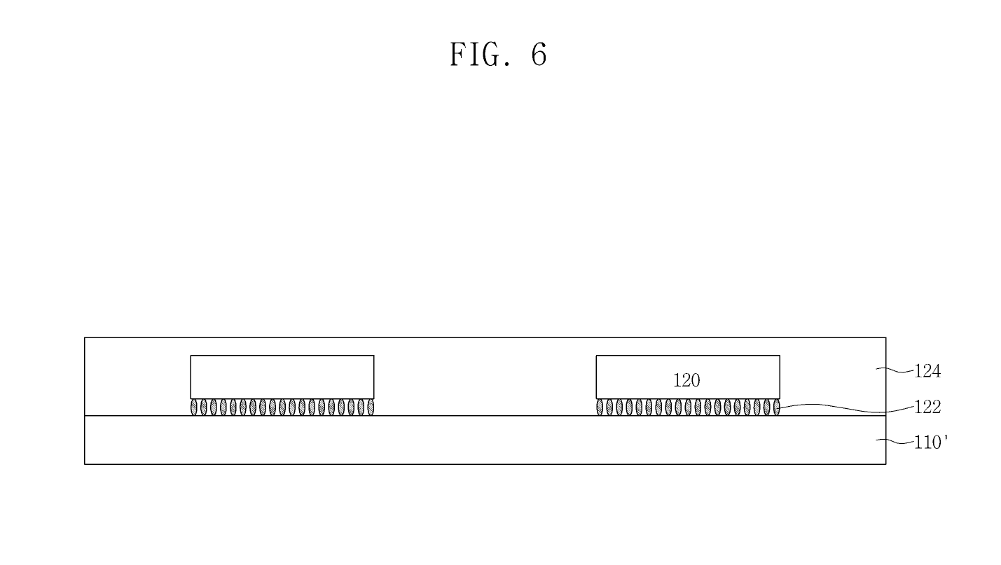

FIG. 6 is a conceptual side cross-sectional view illustrating a method of manufacturing a semiconductor package in accordance with a third embodiment of the inventive concept. In the method of manufacturing a semiconductor package according to the third embodiment, processes other than processes described below are the same as those of the first embodiment and are thus not repeated here. Referring to FIG. 6, the method of manufacturing a semiconductor package according to the third embodiment may include forming a molding material 124 to cover upper surfaces and side surfaces of semiconductor chips 120. Specifically, the molding material 124 may be formed to not only surround the side surfaces of the semiconductor chips 120 and chip bumps 122 below the semiconductor chips 120 but also to cover the upper surfaces of the semiconductor chip 120.

In this case, the MCF mentioned above with respect to the first embodiment may not be attached to the upper surfaces of the semiconductor chips 120 and may be disposed apart from the upper surfaces of the semiconductor chips 120.

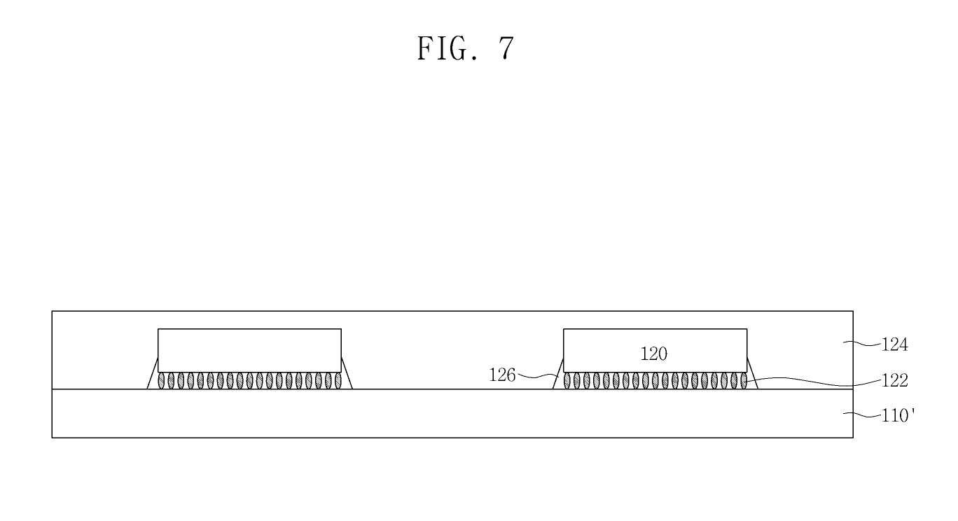

FIG. 7 is a conceptual side cross-sectional view illustrating a method of manufacturing a semiconductor package in accordance with a fourth embodiment of the inventive concept. In the method of manufacturing a semiconductor package according to the fourth embodiment, processes other than processes described below are the same as those of the first embodiment and are thus not described here. Referring to FIG. 7, the method of manufacturing a semiconductor package according to the fourth embodiment may include forming an under-fill material 126 to surround chip bumps 122 before the molding material 124 is formed. Specifically, after the under-fill material 126 is formed, this method may include forming the molding material 124 to surround side surfaces of the under-fill material 126, side surfaces of semiconductor chips 120, and chip bumps 122 below the semiconductor chips 120, and cover upper surfaces of the semiconductor chips 120.

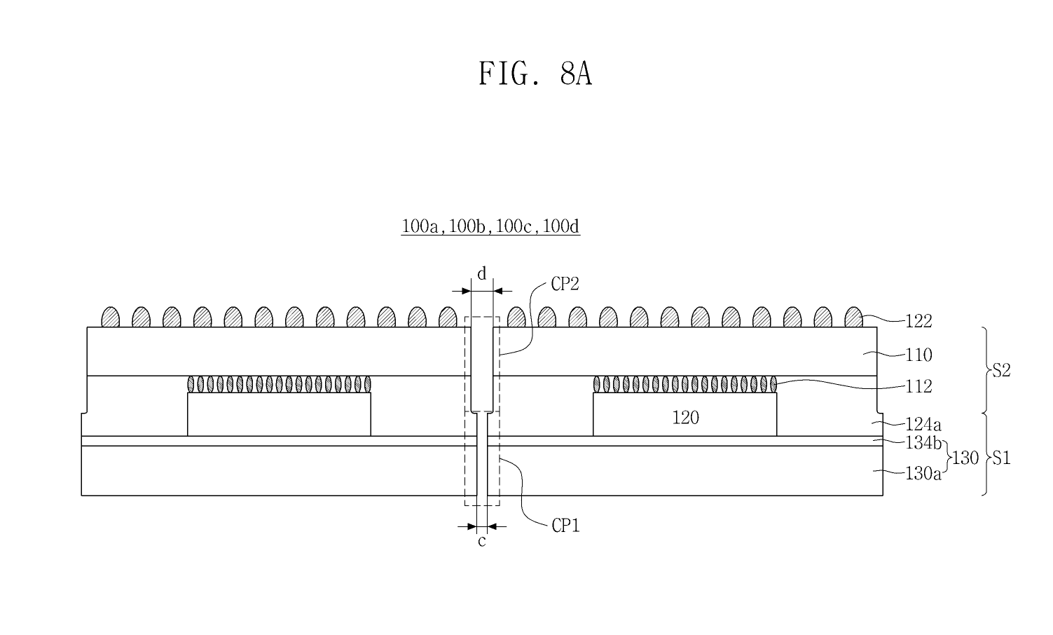

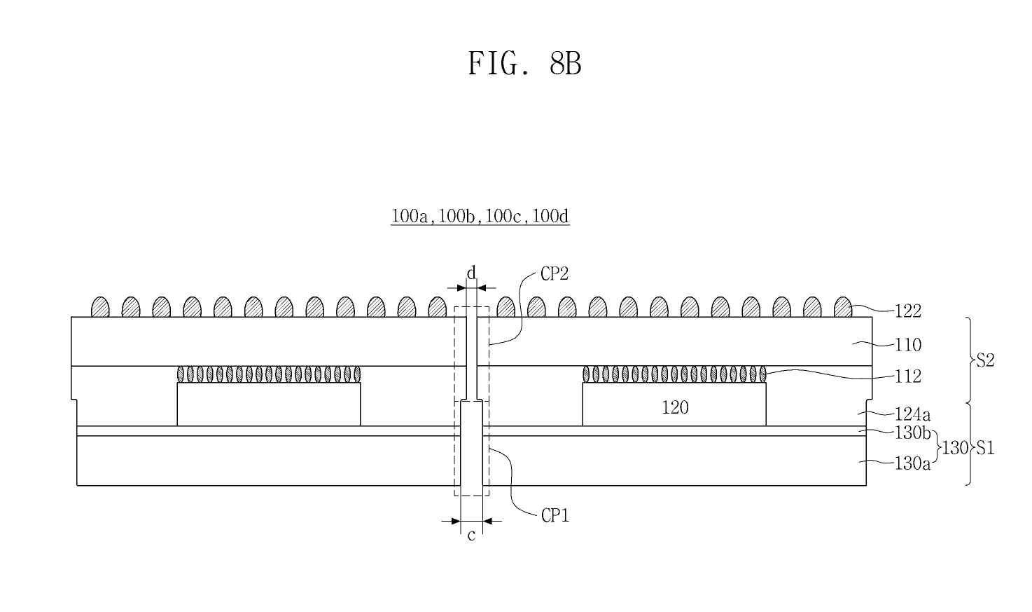

FIGS. 8A and 8B are conceptual side cross-sectional views illustrating cutting methods of performing a singulation process on a large-scale semiconductor package in accordance with various embodiments of the inventive concept.

Referring to FIG. 8A, in a cutting method of performing a singulation process to divide a large-scale semiconductor package into individual semiconductor packages 100a, 100b, 100c, and 100d in accordance with an embodiment of the inventive concept, a first width c of a part CP1 that is cut according to a first cutting process and a second width d of a part CP2 that is cut according to a second cutting process may be different from each other, unlike in the first embodiment described above with reference to FIG. 4E For example, the sizes of the semiconductor packages 100a, 100b, 100c, and 100d into which the large-scale semiconductor package is divided according to the second cutting process may be determined by setting the first width c to be narrower than the second width d. In contrast, referring to FIG. 8B, the sizes of the semiconductor packages 100a, 100b, 100c, and 100d into which the large-scale semiconductor package is divided according to the second cutting process may be determined by setting the first width c to be wider than the second width d.

In each of the semiconductor packages 100a, 100b, 100c, and 100d into which the large-scale semiconductor package is divided according to each of the methods of FIGS. 8A and 8B, a side surface of a heat-spreading part 130 and a corresponding side surface of a portion of the molding material 124a may be aligned with one another in a first vertical direction (or a first vertical plane) according to the first cutting process (hereinafter referred to as first vertically aligned side surfaces S1), and a side surface of a remaining portion of the molding material 124a and a corresponding side surface of the substrate 110 may be aligned with one another in a second vertical direction (or a second vertical plane, which may be seen to be parallel to, but spaced apart from and thus not co-planar with, the first vertical plane) according to the second cutting process (hereinafter referred to as second vertically aligned side surfaces S2). In this case, the first vertically aligned side surfaces S1 and the second vertically aligned side surfaces S2 may not be vertically aligned with one another but instead may be laterally spaced apart from one another as illustrated.

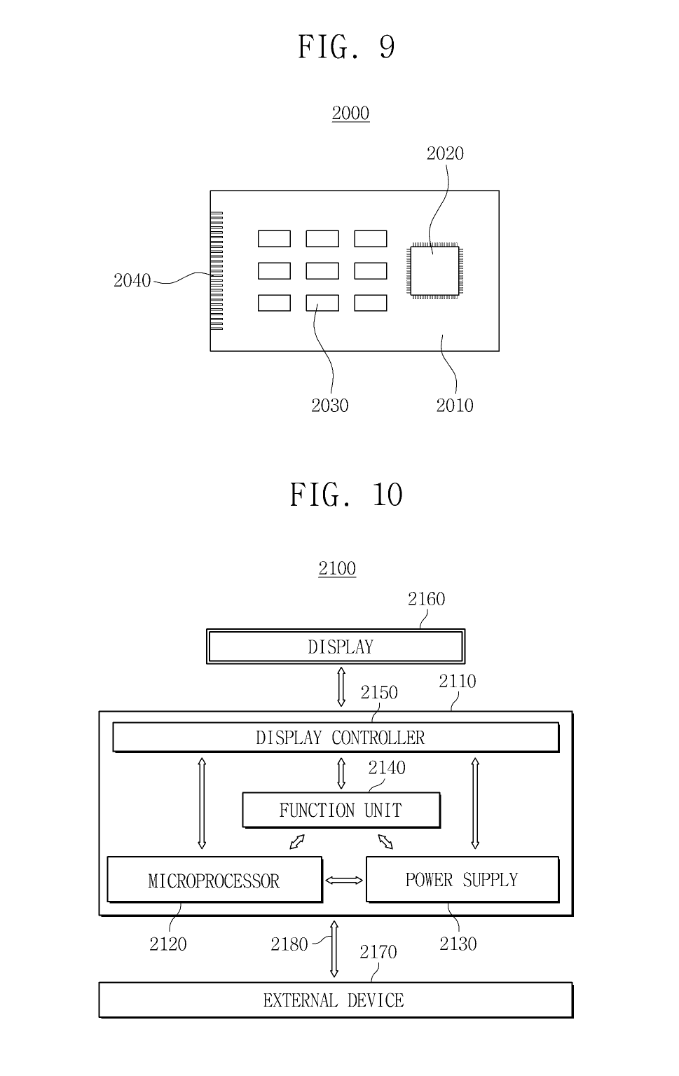

It will be understood that such singulation cuts as are described and illustrated herein may be performed on any one or more or the four peripheral and generally rectangular sides of the semiconductor package 100a, 100b, 100c, or 100d. This will be clear by reference to the top plan view of FIG. 9 described below, which illustrates an application of the invented embodiments in which plural ones of such rectangular semiconductor packages as are described and illustrated herein are arrayed in two dimensions across the upper surface of a typical semiconductor module.

FIG. 9 is a diagram conceptually illustrating a semiconductor module 2000 including the semiconductor packages in accordance with various embodiments of the inventive concept. Referring to FIG. 9, the semiconductor module 2000 in accordance with an embodiment of the inventive concept may include one or more semiconductor devices such as a semiconductor device 2030 mounted on a module substrate 2010. The semiconductor device 2030 may include at least one among the semiconductor packages 100a, 100b, 100c, and 100d in accordance with various embodiments of the inventive concept. Thus, it may be understood that heat is distributed evenly across the entire surface of each of the semiconductor packages within semiconductor module 2000. The semiconductor module 2000 may further include a microprocessor 2020 mounted on the module substrate 2010. Input/output (I/O) terminals 2040 may be disposed at least one side of the module substrate 2010. The semiconductor device 2030 may be mounted on the module substrate 2010 using flip-chip technology or the like.

FIG. 10 is a block diagram conceptually illustrating an electronic system 2100, including any one of the semiconductor packages in accordance with various embodiments of the inventive concept. Referring to FIG. 10, at least one among the semiconductor packages 100a, 100b, 100c, and 100d in accordance with various embodiments of the inventive concept may be applied to the electronic system 2100. The electronic system 2100 may include a body 2110, a microprocessor 2120, a power supply unit 2130, a function unit 2140, and/or a display controller 2150. The body 2110 may be a system board or a mother board including a printed circuit board (PCB), etc. The microprocessor 2120, the power supply unit 2130, the function unit 2140, and the display controller 2150 may be mounted or installed on the body 2110. A display unit 2160 may be disposed on an upper surface of or outside the body 2110. For example, the display unit 2160 may be disposed on the upper surface of the body 2110 and display an image processed by the display controller 2150. A voltage may be applied to the power supply unit 2130 from an external power source or the like, and the power supply unit 2130 may divide the supplied voltage into various voltages, and may then apply the various voltages to the microprocessor 2120, the function unit 2140, the display controller 2150, etc. The microprocessor 2120 may control the function unit 2140 and the display unit 2160 using a voltage applied by the power supply unit 2130. The function unit 2140 may perform various functions of the electronic system 2100. For example, when the electronic system 2100 is a mobile product, such as a mobile phone, the function unit 2140 may include various elements capable of performing dialing, or performing wireless communication (e.g., outputting an image to the display unit 2160, outputting an audio signal via a speaker (not shown), etc.) by communicating with an external device 2170. When the electronic system 2100 includes a camera, the function unit 2140 may act as an image processor. In accordance with an application embodiment of the inventive concept, when the electronic system 2100 is connected to, for example, a memory card so as to expand the memory capacity thereof, the function unit 2140 may be a memory card controller. The functional unit 2140 may exchange a signal with the external device 2170 via a wired/wireless communication unit 2180. When the electronic system 2100 requires a universal serial bus (USB) to expand functions thereof, the function unit 2140 may act as an interface controller. At least one among the semiconductor packages 100a, 100b, 100c, and 100d in accordance with various embodiments of the inventive concept may be included in at least one of the microprocessor 2120 and the function unit 2140.

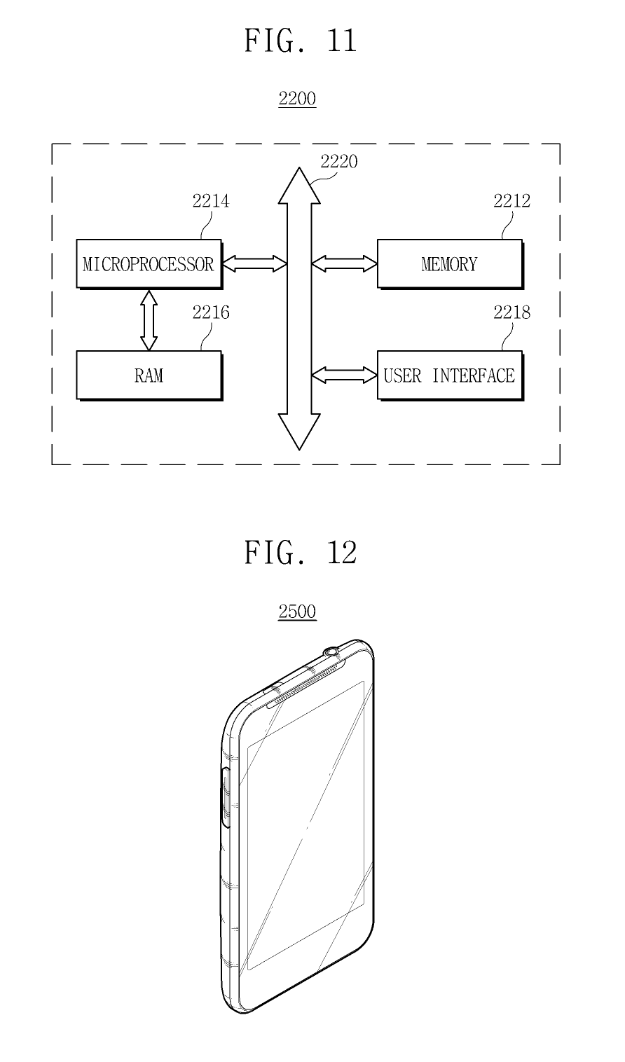

FIG. 11 is a block diagram conceptually illustrating an electronic system 2200 including any one of the semiconductor packages 100a, 100b, 100c, and 100d in accordance with various embodiments of the inventive concept. Referring to FIG. 11, the electronic system 2200 may include at least one among the semiconductor packages 100a, 100b, 100c, and 100d in accordance with various embodiments of the inventive concept. The electronic system 2200 may be included in a mobile apparatus or a computer. For example, the electronic system 2200 may include a memory system 2212, a microprocessor 2214, a random access memory (RAM) 2216, and a user interface 2218 that establishes data communication via a bus 2220. The microprocessor 2214 may program or control the electronic system 2200. The RAM 2216 may be used as an operating memory of the microprocessor 2214. For example, the microprocessor 2214 or the RAM 2216 may include any one of the semiconductor packages 100a, 100b, 100c, and 100d in accordance with various embodiments of the inventive concept. The microprocessor 2214, the RAM 2216, and/or other elements may be assembled in a single package. The user interface 2218 may be used to input data to or output data from the electronic system 2200. The memory system 2212 may store codes for operating the microprocessor 2214, data processed by the microprocessor 2214, or external input data. Although not shown, the memory system 2212 may include a controller and a memory.

FIG. 12 schematically illustrates a mobile wireless phone 2500 including any one of the semiconductor packages 100a, 100b, 100c, and 100d in accordance with various embodiments of the inventive concept. The mobile wireless phone 2500 may be understood as a tablet personal computer (PC). In addition, at least one among semiconductor packages 100a, 100b, 100c, and 100d in accordance with various embodiments of the inventive concept may be used in not only a tablet PC but also a portable computer, such as a notebook computer, an MPEG-1 audio player, an MP3 player, an MP4 player, a navigation system, a solid state disk (SSD), a table computer, an automobile, and a household appliance.

In accordance with the above one or more embodiments of the inventive concept, a thermal conductive film is used as a heat-spreading part, instead of a heat transfer material, and a semiconductor package may be formed to a uniform thickness.

Also, the thermal conductive film is attached to a heat slug such that they are integrated together. Thus, an additional process of applying and hardening a heat emission material may be omitted, thereby shortening a process time.

Also, since the heat-spreading part is of lesser thickness, i.e it is characterized by its thinness, heat radiation efficiency may be maximized

Furthermore, the occurrence of a peeling-off phenomenon between a surface of a molding material and the heat-spreading part may be minimized due to the uniform thickness of the thermal conductive film.

In the present drawings, the names and functions of elements that are not assigned reference numerals or reference numerals assigned without displaying elements thereof in a drawing would be apparent from other drawings of or the detailed description of the present disclosure. Although only representative embodiments of the inventive concept are set forth herein, it would be obvious to those of ordinary skill in the art that features of any one of the representative embodiments or a combination of the features may also be embodied in other embodiments of the inventive concept.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

1. A semiconductor package comprising:
a substrate;
a semiconductor chip attached to an upper surface of the substrate;
a molding material surrounding side surfaces of the semiconductor chip; and
a heat-spreading part disposed on the semiconductor chip,
wherein the heat-spreading part comprises a heat slug and a thermal conductive film, the horizontal areas of which are substantially the same.

2. The semiconductor package of claim 1, wherein a surface of the thermal conductive film that is not attached to the heat slug directly contacts upper surfaces of the semiconductor chip and the molding material.

3. The semiconductor package of claim 1, wherein the thermal conductive film comprises an epoxy resin.

4. The semiconductor package of claim 1, wherein the thermal conductive film comprises aluminum oxide (Al₂O₃), silver, silicon dioxide (SiO₂), aluminum nitride (AlN), or boron nitride (BN).

5. The semiconductor package of claim 1, wherein the molding material surrounds the side surface of the semiconductor chip and covers an upper surface of the semiconductor chip.

6. The semiconductor package of claim 1, wherein the thermal conductive film has a thickness of between approximately 5 and 100 micrometers (μm).

7. The semiconductor package of claim 1, wherein corresponding side surfaces of the heat-spreading part, of the molding material, and of the substrate are vertically aligned with one another.

8. The semiconductor package of claim 1, wherein a side surface of the heat-spreading part and a corresponding side surface of a portion of the molding material adjacent to the heat-spreading part are aligned with each other in a first vertical direction,
wherein the side surface of a remaining portion of the molding material and the side surface of the substrate adjacent to the remaining portion of the molding material are aligned with each other in a second vertical direction, and
wherein the side surfaces aligned in the first vertical direction and the side surfaces aligned in the second vertical direction are not vertically aligned with each other.

9. A semiconductor package comprising:
a substrate;
a semiconductor chip attached to an upper surface of the substrate;
a molding material configured to surround side surfaces of the semiconductor chip; and
a heat-spreading part disposed on the semiconductor chip, and including a thermal conductive film and a heat slug that are integrated together,
wherein the heat-spreading part and a part of the molding material adjacent to the heat-spreading part comprise side surfaces aligned in a first vertical direction, and
a remaining part of the molding material and the substrate comprises side surfaces aligned in a second vertical direction.

10. The semiconductor package of claim 9, wherein the side surfaces aligned in the first vertical direction and the side surfaces aligned in the second vertical direction are vertically aligned with each other.

11. The semiconductor package of claim 9, wherein the side surfaces aligned in the first vertical direction and the side surfaces aligned in the second vertical direction are not vertically aligned with each other.

12. The semiconductor package of claim 9, further comprising a thermal conductive adhesive tape adhered onto the thermal conductive film.

13. The semiconductor package of claim 9, wherein an under-fill material is filled between the substrate and the semiconductor chip.

14. The semiconductor package of claim 13, wherein the molding material surrounds side surfaces of the under-fill material and the side surfaces of the semiconductor chip.

15. The semiconductor package of claim 13, wherein the molding material surrounds side surfaces of the under-fill material and the side surfaces of the semiconductor chip, and wherein the molding material covers an upper surface of the semiconductor chip.

16-20. (canceled)
